(19) United States
(12) Patent Application Publication
(10) Pub. No.: US 2025/0243602 A1
(43) Pub. Date: Jul. 31, 2025

(54) PROCESS FOR PRODUCING CRYSTALS, PARTICULARLY POLYCRYSTALS

(71) Applicants: Volodymyr TARANYUK, Kharkiv (UA); Vadim GAYSHAN, Sudbury, MA (US)

(72) Inventors: Volodymyr TARANYUK, Kharkiv (UA); Vadim GAYSHAN, Sudbury, MA (US)

(21) Appl. No.: 19/078,597

(22) Filed: Mar. 13, 2025

(30) Foreign Application Priority Data
Jan. 5, 2024 (UA) A 2024 02310

(51) Int. Cl. C30B 28/04; C30B 29/12; C30B 33/02

(52) U.S. Cl. CPC C30B 28/04; C30B 29/12; C30B 33/02

(57) ABSTRACT

The invention is a process for producing crystals (polycrystals) that comprises steps of: evacuating, melting a raw material in a container by means of a resistance heater to form a skull layer of 5-10 mm, crystallizing a melt of the raw material, annealing and cooling the crystal, separating the skull layer. The container is coated inside with a metal foil having a thickness of 0.04-0.15 mm; the steps of melting the raw material, crystallizing, annealing and cooling the crystal are performed in a double-layered shell composed of the metal foil and the skull layer; after the crystallization step, the crystal is annealed in a separate annealing furnace. The invention allows to: prevent crystal cracking, produce the crystal without any internal stresses; reduce the raw material mass consumed to form the skull layer; increase the size and the weight of the produced crystal; reduce energy consumption.

### FIELD OF THE INVENTION

The invention relates to a technology for producing crystals by a skull method, namely, to a process for producing crystals, particularly polycrystals. The claimed process may be used in manufacturing crystals, particularly polycrystals of various sizes, including alkali-halide scintillation crystals.

### PRIOR ART

A known process for producing thallium-activated sodium iodide single crystals includes melting a raw material and crystallization of the produced melt take place in a mold that is coated with a graphite foil. The crystallization of the melt is performed by cooling a center of the mold with air, while controlling the air flow rate to the area being. This process is used to grow scintillation large-area NaI(Tl) crystals that, however, have a thickness of not more than 17 mm. Besides, use of the graphite foil results in contamination of the crystal with graphite in a form of black inclusions, thereby facilitating deterioration of the crystal quality. Also, when the graphite foil is used, annealing and cooling of the crystal must be performed only in a furnace with no oxygen access in order to prevent burning of the graphite foil, thereby making the equipment more complex. Therefore, this process does not allow to produce a high-quality crystal.

Another method of manufacturing large crystal bodies (crystals) comprises steps of producing a melted raw material, directional crystallizing the produced melt, its cooling in a mold that is coated with a protective layer, including a graphite foil or a metal (platinum, iridium) foil having a graphite layer, or other layers that are not separated from this crystal after the crystal is produced. This protective layer is intended to protect a surface of a final product, i.e., the produced crystal: this protective layer remains on the crystal surface and is not removed. According to this method, the melt contacts the material that coats the mold, and in view of this, the coating material must be chemically inert relative to the melt material and have a melting temperature greater than a melting temperature of the crystal being grown. These materials may be only precious metals, namely, platinum, iridium, thereby significantly increasing crystal production costs, or graphite that may contaminate the melt and the crystal with black inclusions, thereby resulting in deterioration of the crystal quality. Also, it is necessary to have a technology for applying the coating on the mold without any gaps, because any discharge of the melt through the coating will result in interaction between the melt and the mold, contamination of the melt with the mold material and, thus, production of a low-quality crystal. Therefore, this method does not allow to implement the technology for producing/growing high-quality crystals, particularly large-area polycrystals, without high costs, because a cost price for producing the crystals according to this technology is very high.

Yet another method for producing single crystals, including large-area single crystals, has an objective to provide an affordable technology for growing single crystals, including large-area single crystals, while reducing a cost price of the entire process. This technology comprises steps of loading a raw material into a container that is placed in a cooling vacuum chamber, melting the raw material to form a melt by means of a resistance heater that is positioned above the container, and an area of the heater is less than an area of the container for formation of a skull layer near walls of the container having a thickness of 5-10 mm, maintaining the melt, performing crystallization by reducing a temperature of the heater, while continuously controlling a level of the melt and a crucible temperature. At the same time, prior to loading the raw material to a bottom of the container, at least one seed single crystal is mounted with a gap of 5-15 mm from its walls, the seed single crystal has a height of at least 20 mm and not more than ⅔ of the container height, and further melting of the raw material and crystallization are performed at corresponding parameters. In this method, the temperature of the container bottom is controlled so as to be within 0.65-0.75 of the melting temperature of the crystal being grown, i.e., it is 429.7° C.-495.8° C. for NaI(Tl) crystal. Under these conditions, the interval of thickness values of an unmelted layer along the container bottom is 10-15 mm that is not an optimal interval and reduces the process efficiency. Also, at these temperatures of the container bottom, the skull layer adheres to the container, thereby resulting in cracking of the crystal during its cooling. Cooling of the crystal that is located in the container in the vacuum water-cooling chamber, where the melt crystallization took place, results in accumulation of internal stresses within the crystal and its cracking during its cooling or further processing. Therefore, this method does not allow to produce a high-quality crystal without internal stresses and without any cracking during further processing.

Another technical solution is a method for producing crystals, particularly large-area crystal plates, it implies:
loading a raw material into a container,
placing the container loaded with the raw material into a cooling vacuum chamber that is evacuated to forevacuum,
heating and melting the raw material in a skull to form an optimal thickness of a skull layer by means of a resistance heater positioned above the container and in parallel to a melt surface of the raw material, the resistance heater has a working heating surface having an area that is less than an area of an exposed upper part of the container and it has parameters that allow to produce the skull layer along inner surfaces of walls and bottom of the container having a thickness of 5-10 mm,
further directional crystallizing the melt of the raw material by reducing a temperature of the resistance heater according to a given program,
annealing the produced crystal,
cooling the annealed crystal,
separating the skull layer.

This process is a new technology for producing crystals, including crystal plates, by a skull method, it is simple to implement, it does not require any expensive equipment and allows to produce crystals having scintillation characteristics at a required level. However, this process has room for improvement.

Upon implementation of this technology, the given optimal thickness of the skull layer along the walls of the container is achieved due to the area of the resistance heater, while at the bottom of the container, it is achieved due to the power of the resistance heater or its approach to the melt, thus, there is no control of both the process and the thickness of the formed skull layer. Implementation of this process would be possible if system parameters are rigidly fixed, such as: particle size and bulk density of the raw material loaded into the container, geometrical sizes of the crystal and its weight, cooling temperature of the vacuum chamber, and other parameters. If at least one of the parameters is changed, an individual experimental procedure should be performed for selecting geometrical parameters of the resistance heater and its power in order to ensure required conditions for growing the crystal and obtaining the optimal thickness of the skull layer of 5-10 mm, but it requires much time and resources, as well as it is economically unacceptable. Also, the non-optimal selection of area or power of the resistance heater results in significant or complete melting of the skull layer along the container side walls and bottom, thus, it will lead either to adherence of the crystal to the rigid walls of the container and its further cracking during cooling or to contamination of the melt with the container material, or to melting of the container and discharge of the melt to the vacuum chamber volume. If the skull layer, i.e., the layer of the partially unmelted raw material of a rather high thickness, remains, it will result in reduction of size of the crystal being grown, i.e., in reduction of the process efficiency. This method establishes an optimal interval of values for the thickness of the skull layer; however, practical implementation of the technology does not allow to achieve this optimal thickness of the skull layer, particularly along the inner surface of the container bottom.

Also, this method implies annealing and cooling the crystal placed in the container in the water-cooling vacuum chamber, where previous steps have been performed, namely, in the container arranged therein, where the bottom part of the container is cold, while the upper part thereof is heated, however, in this case, annealing and cooling the crystal are performed in a temperature field with a high temperature gradient, because the crystal bottom is located in the cold area, while the top thereof is located in the hot area, thereby leading to occurrence of internal stresses within the crystal and its cracking during cooling and further processing.

Besides, annealing and cooling of the crystal are performed within several days within the same equipment that has been used for performing all the previous process steps before annealing and cooling, thereby resulting in a reduction of usage efficiency of the complex manufacturing equipment (the water-cooling vacuum chamber, the container, the resistance heater). Annealing and cooling the crystal in the same equipment as the previous steps make it impossible to perform, after completion of the crystallization, the next cycle of crystal growing in the same equipment, because the equipment turnover is reduced, thereby increasing manufacturing costs.

Therefore, in view of said drawbacks, this method does not allow to increase the crystal quality significantly, to increase the process efficiency, and to reduce energy costs for implementation of the process.

In order to produce a high-quality crystal, to increase the process efficiency, and to reduce energy costs for the manufacturing process, it is proposed to improve the known technology by the claimed process.

An objective underlying the invention is to provide a process for producing crystals, particularly polycrystals, that could ensure, owing to all its essential features, a novel set of features and novel features, achievement of the following technical effects:
maximum reduction or removal of internal stresses and elimination of the crystal cracking during manufacturing (growing) of the crystal, and, thus, production of the crystal, particularly the polycrystal having an assured high quality without any internal stresses;
reduction of the consumed weight of the raw material for formation of the skull layer during manufacturing (growing) of the crystal, and, thus, achievement of the increase of size and weight of the crystal, particularly the polycrystal;
reduction of energy costs for conduction of the process for producing the crystal, particularly the polycrystal, as compared to the closest analog.

### SUMMARY OF THE INVENTION

The objective is achieved by the claimed process for producing crystals, the process comprises steps of:
loading a raw material into a container,
placing the container loaded with the raw material into a cooling vacuum chamber that is evacuated to forevacuum,
heating and melting the raw material in a skull to form an optimal thickness of a skull layer by means of a resistance heater positioned above the container and in parallel to a melt surface of the raw material, the resistance heater has a working heating surface having an area that is less than an area of an exposed upper part of the container and it has parameters that allow to produce the skull layer along inner surfaces of walls and bottom of the container having a thickness of 5-10 mm,
further directional crystallizing the melt of the raw material by reducing a temperature of the resistance heater according to a given program,
annealing the produced crystal,
cooling the annealed crystal,
separating the skull layer.

Novel features are as follows:
the process comprises, before the step of loading the container with the raw material, a step of coating an inner surface of the container for growing the crystal with a protective metal foil layer having a thickness of 0.04-0.15 mm,
the steps of producing the melt of the raw material, directional crystallizing, annealing and cooling the annealed crystal are performed in a double-layered protective shell that is formed along the inner surfaces of the walls and the bottom of the container by the protective metal foil layer and the skull layer of the raw material,
after pre-heating by the resistance heater and pre-melting the raw material, the further step of melting the raw material comprises adjusting a temperature T₁ of the resistance heater based on controlling measurement values of a temperature T₂ of a side wall of the container and a temperature T₃ of the bottom of the container. The temperature T₁ of the resistance heater is fixed after either one of the temperatures T₂ or T₃ reaches a value that falls within an interval (a range) of values that corresponds to a temperature control criterion C_{tc} that is 0.76-0.8 of a melting temperature value T₄ of the crystal being produced, namely, C_{tc}=(0.76×T₄):(0.8×T₄).

Explanation: in other words, at the step of adjusting the temperature T₁ of the resistance heater based on controlling the measurement values of the temperature T₂ of the side wall of the container and the temperature T₃ of the bottom of the container, fixing the temperature T₁ in order to stop further increase of heating the main mass of the raw material melt and the formed skull layer is performed based on the value of one of the temperatures T₂ or T₃ according to temperature control criterion C_{tc} that has been obtained first, i.e., that has fallen first within the interval that corresponds to the temperature control criterion C_{tc}=(0.76×T₄)+(0.8×T₄), and the value of one of the temperatures T₂ or T₃ that has reached first the interval of the control criterion C_{tc} and that serves as a basis for fixing the temperature T₁ of the resistance heater should not exceed the value (0.8×T₄)° C. and should not be lower than (0.76×T₄)° C., thereby making it impossible to exceed the limit (0.8×T₄)° C. also for the second temperature from the temperatures T₂ and T₃ that has not reached first the control interval C_{tc}; when the temperature T₂ and the temperature T₃ have simultaneously, i.e., at the very same moment, reached the value that falls within the temperature interval according to the criterion C_{tc} that is 0.76-0.8 of the crystal melting temperature T₄, the temperature T₁ of the resistance heater is fixed, i.e., its increase is stopped starting from the moment of this simultaneous falling of the values of the temperature T₂ and the temperature T₃ within the temperature interval according to the criterion C_{tc}=(0.76×T₄):(0.8×T₄), i.e., the value of the temperature T₂, as well as the value of the temperature T₃, must not exceed the value 0.8 of the value of the temperature T₄ and must not be lower than 0.76 of the value of the temperature T₄;
after the step of directional crystallizing is completed, the step of annealing the crystal is performed in a separate annealing furnace at a temperature T₅ having a value of 0.8-0.9 of the crystal melting temperature value T₄ of the crystal being produced: T₅=(0.8×T₄):(0.9×T₄).

This process is characterized by the below-mentioned features that develop, specify, and diversify the set of features and the features of independent claim, also for some specific conditions and embodiments of the invention.

An aluminum foil layer having an aluminum content of at least 98.5% is used as a metal component of the double-layered protective shell.

The step of melting the raw material comprises controlling the temperature measurement value T₂ of one of the side walls of the container which is performed in an upper external middle zone of the side wall of the container, while controlling the temperature measurement value T₃ of the bottom of the container is performed in a central external zone of the bottom of the container.

The further melting the raw material for formation and maintaining the optimal thickness of the skull layer within 5-10 mm by adjusting the temperature T₁ of the resistance heater based on controlling the temperature measurement values T₂ and T₃ according to the interval of values of the temperature control criterion C_{tc}=(0.76×T₄):(0.8×T₄) takes place for 4-8 hours after pre-heating and pre-melting the raw material, and then the produced melt of the raw material having the formed skull layer is maintained for 1-2 hours.

An inner working volume of the separate annealing furnace is heated to the temperature T₅ before the container with the crystal is loaded therein, and the crystal is annealed at this temperature for 1-5 hours.

After the steps of annealing and further cooling the crystal, the double-layered protective shell is separated from the annealed and cooled crystal successively, namely, firstly, the aluminum foil layer is separated from the skull layer, and then, the skull layer is separated from the crystal.

### Inventive Step

The set of all essential features of the claimed process for producing crystals, particularly polycrystals, its novel features, the novel set of all the features, namely: steps of loading the raw material into the container, placing the container loaded with the raw material into the cooling vacuum chamber that is evacuated to forevacuum, heating and melting the raw material in the skull to form the optimal thickness of the skull layer by means of the resistance heater positioned above the container and in parallel to the melt surface of the raw material, the resistance heater has the working heating surface having the area that is less than the area of the exposed upper part of the container and it has parameters that allow to produce the skull layer along inner surfaces of walls and bottom of the container having a thickness of 5-10 mm, further directional crystallizing the melt of the raw material by reducing the temperature of the resistance heater according to the given program, annealing the produced crystal, cooling the annealed crystal, separating the skull layer, according to the invention, the process comprises, before the step of loading the container with the raw material, coating the inner surface of the container for growing the crystal with a protective metal foil layer having the thickness of 0.04-0.15 mm, and the steps of producing the melt of the raw material, directional crystallizing, annealing and cooling the annealed crystal are performed in the double-layered protective shell that is formed along the inner surfaces of the walls and the bottom of the container by the protective metal foil layer and the skull layer of the raw material, and the step of melting the raw material comprises adjusting the temperature T₁ of the resistance heater based on controlling measurement values of the temperature T₂ of the side wall of the container and the temperature T₃ of the bottom of the container, while correspondingly fixing the temperature T₁ of the resistance heater immediately after either one of the temperatures T₂ or T₃ or both temperatures T₂ and T₃ simultaneously reached the value that falls within the interval that corresponds to the temperature control criterion C_{tc} that is 0.76-0.8 of a crystal melting temperature value T₄ of the crystal being grown, and after the step of directional crystallizing is completed, the step of annealing the crystal is performed in a separate annealing furnace at a temperature T₅ having a value of 0.8-0.9 of the crystal melting temperature value T₄ of the crystal being grown, allow to ensure achievement, upon implementation of this process, of the following technical effects:
production of the crystal, particularly the polycrystal having the assured high quality without any internal stresses due to elimination of accumulation of these stresses and cracking of the crystal;
increase of the size of the crystal, particularly the polycrystal, and, thus, increase of its weight, which allowed to increase the process efficiency by up to 10% due to reduction of the mass of the raw material consumed for formation of the skull layer as compared to the closest analog;
reduction of energy costs for conduction of the process by down to 29% as compared to the closest analog.

A cause-and-effect relationship between the novel features of the claimed process and the technical effects that are achieved upon its implementation is as follows.

According to the invention, before the step of loading the raw material, the inner surface of the container for growing the crystal is coated with the protective layer in the form of the metal aluminum foil having the thickness of 0.04-0.15 mm, while using it as a metal component in a double-layered shell that is formed by the layer of this foil and by the skull layer of the raw material, where the following technological steps of the process for producing the crystal take place: melting the raw material, crystallizing the melt, annealing and cooling the annealed crystal. The metal aluminum layer serves as a protective layer in all the above-mentioned steps in order to avoid adherence of the skull layer to the container and to prevent accumulation of any internal stresses in the crystal and its further cracking. High elasticity of this foil allows to prevent accumulation of any internal stresses and cracking of the crystal during further cooling due to a difference between thermal expansion coefficients of the crystal and the container material. After the crystal is annealed and cooled, the foil is easily removed from the skull layer. If the foil having the thickness of less than 0.04 mm is used, it will be difficult to remove the foil from the skull layer surface. The foil having the thickness of more than 0.15 mm is not sufficiently elastic, limits deformations of the crystal during cooling, thereby resulting in creation of internal stresses.

When the claimed process is implemented, during melting of the raw material, the formation of the skull layer is started and finished. The skull layer, i.e., the protective layer that together with the aluminum foil layer represents the double-layered protective shell and that avoids any contact between the inner working surfaces of the walls and the bottom of the container coated with the aluminum foil layer and the melt of the raw material, is formed on the entire area of the inner working surfaces coated with the protective layer of the aluminum foil along the walls and the bottom of the container, namely, on the entire surface of this aluminum foil that adjoins to the raw material mass being melt from the start of melting the raw material to its finish as a result of the partial unmelting of the raw material along the above-mentioned surface of the aluminum foil layer. The skull layer formed during the melting of the raw material is a processing medium in the form of the partially unmelted raw material having an aggregate state being a plastic and elastic mass.

Therefore, the process of melting the raw material takes place in the double-layered protective shell that consists of the protective aluminum foil layer and the protective skull layer that is formed to the optimal minimum thickness during the melting of the raw material. The skull layer avoids any contact between the melted raw material and the metal foil, while the metal aluminum foil avoids adherence of the skull layer to the walls and the bottom of the container.

Use of the metal aluminum foil in the claimed process, including for performing the steps of melting the raw material, crystallizing the melt, annealing, and cooling the annealed crystal, in the double-layered protective shell having the metal component being the aluminum foil layer having the thickness of 0.04-0.15 mm, surprisingly allowed to reduce the energy costs of the entire crystal growing process.

According to the invention, the fact that the step of further melting the raw material comprises adjusting the temperature T₁ of the resistance heater based on controlling the measurement values of the temperature T₂ of the side wall of the container and the temperature T₃ of the bottom of the container, while correspondingly fixing the temperature T₁ of the resistance heater immediately after one of the temperatures T₂ or T₃ reached the value (i.e., after the temperatures T₂, T₃ fell within the interval of temperature control criterion C_{tc}) that falls within the interval of this criterion C^{tc} that is 0.76-0.8 of the melting temperature value T₄ of the crystal being produced, namely C_{tc}=(0.76×T₄):(0.8×T₄), while when both the temperature T₂ and the temperature T₃ simultaneously, i.e., at the very same moment, reached the value according to the above-mentioned criterion C_{tc}, and fixing the temperature T₁ of the resistance heater from the moment of this simultaneous falling of the values of the temperature T₂ and the temperature T₃ within the temperature interval according to the criterion C_{tc}, ensures optimal heating and avoids overheating the technological mass that is used for the formation of the skull layer having the optimal minimum thickness 5-10 mm along the side wall and the bottom of the container.

Tests have demonstrated that a melting system of the raw material mass is complex in terms of its dynamics, temperature changes over time, i.e., a non-stationary temperature field, non-uniformity and unpredictability of the temperatures across the entire volume, and other factors. Thus, it is important to provide an assured adjustment of the important parameter of this technological process that defines quantitative and qualitative characteristics of the produced crystal, namely, temperature, based on high-precision and fast-acting measurement of its values. The claimed process allows, owing to use of the temperature control criterion C_{tc}=(0.76×T₄): (0.8×T₄), to evaluate the optimal degree of heating the processing medium during the melting of the raw material precisely and assuredly. Numerous studies have confirmed the proposal about boundary (endpoint) values of the temperatures of the side wall and the bottom of the container that assure timely adjustment, i.e., fixation and termination of further increase of the temperature of the resistance heater for heating the processing medium. Those specifically proposed values of the interval (0.76×T₄):(0.8×T₄) are optimal for defining this adjustment of the temperature of the resistance heater T₁: the values of the temperature T₂ or T₃, or T₂ and T₃ together within this specific interval, are fixed timely and assuredly by fixing the temperature of the resistance heater. The temperature values T₂ and T₃ are timely fixed from the moment of their falling within the above-mentioned interval to the moment of their “exit”, i.e., they make it impossible to reach the moment of “exit” from this interval and, thus, avoiding any overheat of the processing medium.

Owing to conduction of the melting process of the raw material using C_{tc}, i.e., the temperature control criterion for the temperature T₂ of the side wall and the temperature T₃ of the bottom of the container, the temperature T₁ of the resistance heater is adjusted, it is timely fixed in order to stop any further temperature increase during further heating of the processing medium in the stationary heat field (i.e., without any temperature increase in the course of time), thereby ensuring assured formation of the optimal thickness of the skull layer of 5-10 mm, the limit of the optimal heating of the technological mass being a part of the raw material used to form the skull layer, and maintaining the formed skull layer, i.e., avoiding its complete melting as a result of overheating. Therefore, in the process of melting the raw material, the optimal thickness is formed, and the formed skull layer of this thickness is assuredly maintained.

According to the proposed temperature control criterion C_{tc}, the temperature T₂ of the side wall and/or the temperature T₃ of the container bottom must be within the range of this criterion 0.76-0.8 of the melting temperature T₄ of the crystal and must not exceed 0.8 of the melting temperature T₄ of the crystal being grown and must not be less than 0.76 of the melting temperature T₄ of the crystal being grown. When the values of the temperature T₂ or the temperature T₃ used for adjusting, i.e., fixing the temperature T₁ of the resistance heater, are greater than (0.8×T₄), the probability of complete melting of the protective skull layer and, thus, the occurrence of the contact between the raw material melt with the aluminum foil that coats the container walls or with the wall of the aluminum container, and contamination of the raw material melt is increased, or even the container wall is melted and the melt discharges therefrom. When the temperature T₂ or the temperature T₃ is less than (0.76×T₄), the optimal thickness of the skull layer of 5-10 mm will not be achieved assuredly. At the same time, the values of the temperature T₂ and the temperature T₃ being (0.76×T₄) is a temperature threshold when these temperatures fall within the interval of C_{tc} that allows to timely fix the temperatures being controlled.

Annealing the crystal after the completion of the crystallization in the separate annealing furnace allows not only to avoid formation of the internal stresses within the crystal that result in cracking of the crystal during cooling and further processing, but also to effectively use the manufacturing equipment to produce the crystal and to reduce the energy consumption for annealing the crystal.

The value of the crystal annealing temperature T₅ must be within 0.8-0.9 of the melting temperature T₄ of the crystal being grown in order to eliminate the internal stresses in the crystal that are formed during the crystallization process and during further stages of its processing. The temperature value T₅ of less than (0.8×T₄) will not ensure relaxation of the internal stresses. The temperature value T₅ that is greater than (0.9×T₄) is excessive.

Use of the metal double-layered protective shell being the aluminum foil having the aluminum content of at least 98.5% ensures qualitative functional properties of this foil as a protective layer. The coating of the internal working surface of the container with the metal aluminum foil is provided to avoid adherence of the skull layer to the internal working surface of the container, i.e., the aluminum foil layer is used as an additional protective layer, i.e., the increased assurance that the technological process will be performed without any contact between the skull layer and the internal working surface of the container. Upon conduction of first experimental tests of the claimed process, it was surprisingly seen that the energy consumption for the process conduction was reduced significantly, while further comparative cycles of the technology using the aluminum foil according to the claimed process confirmed the positive influence of this foil onto saving the electrical energy. Probably, owing to shielding and thermal insulating properties of the aluminum foil, even a thin layer of the aluminum foil together with other factors ensures a synergistic effect that causes preservation of the thermal energy and, thus, the electrical energy.

The step of melting the raw material comprises controlling the measurement value of the temperature T₂ of the side wall of the container in the upper external middle zone of the container and controlling the measurement value of the temperature T₃ of the container bottom in the central external zone of the container, i.e., potentially, in the hottest areas, and it assures maximum precision of the temperature characteristics that are necessary for adjustment of the process of melting the raw material.

The further melting the raw material for formation and maintaining the optimal assured thickness of the skull layer within 5-10 mm by adjusting with the corresponding fixation of the temperature T₁ of the resistance heater and termination of further increase of this temperature based on controlling the temperature measurement values T₂ and T₃ according to the interval of values of the temperature control criterion C_{tc}=(0.76×T₄):(0.8×T₄) for 4-8 hours after pre-heating and pre-melting of the raw material and further maintaining the obtained melt of the raw material with the formed skull layer for 1-2 hours are necessary periods to perform the complete cycle of effective temperature adjustment during melting the raw material.

In this way, the assured control of the process of formation and obtaining the optimal minimum thickness of the skull layer is performed.

Annealing the produced crystal at the temperature T₅ for 1-5 hours in the separate annealing furnace that is heated before loading the crystal to the temperature T₅ allows to reduce energy costs as well as to reduce operational costs due to a possibility of increasing the turnover of the equipment for conduction of subsequent technological cycles of the crystal growing.

The sequential separation of the double-layered protective shell from the crystal that is annealed and cooled after annealing, i.e., firstly, light separation of the aluminum foil layer from the skull layer followed by separation of the skull layer from the crystal, are final steps of the claimed technological process for producing the crack-free crystal, particularly for producing the polycrystal without any internal stresses.

The claimed process has been tested in the experimental and manufacturing environment, and these tests have confirmed the achievement of the technical effects upon implementation of this process.

The implementation of the above-described novel technological cycles, the novel set of technological steps, namely, coating the internal surface of the container with the protective aluminum foil layer having the optimal thickness, performing, in the double-layered protective shell, melting the raw material, crystallization, annealing the crystal and its cooling, adjusting, fixing, maintaining the temperature and time modes when melting the raw material using the proposed temperature control criterion of the walls and the bottom of the container, annealing the crystal in the separate annealing furnace at the temperature of 0.8-0.9 of the melting temperature of the crystal, using the novel parameters and features of these steps according to the claims has ensured achievement of the following technical effects:
production of the crystal, particularly the polycrystal having the assured high quality without any internal stresses due to maximum reduction or elimination of accumulation of these stresses and due to elimination of cracking of the crystal;
increase of the size of the crystal, particularly the polycrystal, and, thus, increase of its weight, that allowed to increase the process efficiency by up to 10% due to reduction of the mass of the raw material consumed for formation of the skull layer;
reduction of energy consumption for conduction of the process by down to 29%.

Upon implementation of the claimed process, the technical effects are achieved particularly within the quantitative parameters (characteristics) of the process, while the technical effects are not achieved outside these intervals of values.

Examples of practical implementation of the process.

Industrial applicability of the invention is described in Examples 1, 2, 3, 4, 5 of its practical implementation, as well as it is illustrated in the Procedural scheme of implementation of the claimed process that is provided in Table 1 (for the Examples 1, 2).

At the same time, in order to ensure the complete and detailed illustration of the practical implementation of the claimed process, the content of the steps of evacuating with the simultaneous heating of the container with the raw material, using argon, further heating and maintaining the raw material for its melting, crystallizing the produced melt, its cooling after completion of the crystallization, are provided in the Examples of practical implementation of the process according to technologies known from the technological practice, according to which, the characteristics (parameters) of the temperature and/or time modes are set for each of the above-mentioned steps depending on certain factors, including depending on the size of the crystal being grown.

The procedural scheme of implementation of the claimed process (according to Example 1 and Example 2 of the practical implementation of the process).

TABLE 1

| No. | Step | Parameters, characteristics |
|---|---|---|
| 1 | Coating the internal surface of the | Dimensions of the container may be, e.g., as follows: |
| | container with the aluminum foil. | 500 mm × 500 mm × 170 mm. The container may |
| | | have any arbitrary geometric shape; Aluminum foil: |
| | | thickness is 0.1 mm; having an aluminum content |
| | | of at least 98.5% |
| 2 | Loading the raw material into a | Example 1: 99 kg of NaI mixture (99 wt. %) and |
| | container: | 1 kg of TlI (1 wt. %); |
| | mixture of sodium iodide NaI and | Example 2: 99.5 kg of NaI (99.5 wt. %), 0.5 kg of |
| | thallium iodide TlI (Example 1) | TlI (0.5 wt. %); and TlI is added separately to |
| | or sodium iodide NaI (Example 2) | the melt of the raw material |
| 3 | Mounting the container loaded | Specific parameters and characteristics are absent |
| | with the raw material into the | |
| | water-cooling vacuum chamber. | |
| 4 | Installing thermocouples on the | Example 1: One thermocouple is located at the |
| | wall and the bottom of the container | container bottom, while another thermocouple is |
| | for measuring the temperature. | located on one of its side walls; |
| | | Example 2: The number of the thermocouples may |
| | | be higher, e.g.: two thermocouples at the bottom |
| | | and one thermocouple on either of the side walls |
| 5 | Positioning the resistance heater at | The dimensions of the resistance heater are 400 × 400 |
| | the distance of 10 mm above the | mm. The geometric shape of the heating working |
| | exposed upper part of the container | surface of the resistance heater corresponds to the |
| | with the raw material. The resistance | shape of the exposed upper part of the container. |
| | heater, particularly its heating | The area of the heating working surface of the |
| | working surface, is positioned | resistance heater is less than the area of the exposed |
| | horizontally and in parallel to the | upper part of the container and, thus, less than the area |
| | upper surface of the mass of the raw | of the upper surface of the mass of the raw material |
| | material loaded into the container | loaded into the container (thus, it is less than the upper |
| | (i.e., in parallel to the surface of the | surface of the future melt of the raw material). |
| | future melt of this raw material). | |

| 1 | 2 | 3 |
|---|---|---|
| 6 | Evacuating the vacuum cooling | Evacuating for 48 hours and the simultaneous heating: |
| | chamber to forevacuum, while at the | 6.1. During 1 hour from the start of evacuation and |
| | same time continuously heating the | simultaneous heating, the temperature T₁ of the |
| | container and the raw material loaded | resistance heater is increased up to 300° C., and this |
| | therein. During this time period, the | temperature is maintained for the next 23 hours of |
| | steps of heating and the simultaneous | evacuating. |
| | evacuating are performed by | 6.2. Then, the temperature T₁ is increased up to |
| | periodically increasing the temperature | 500° C. for 1 hour, and it is maintained during the |
| | of the resistance heater and with | entire remained period of evacuating, namely, for |
| | corresponding time delays (6.1, 6.2). | the next 23 hours. |
| 7 | 7.1. After the steps of evacuating and | 7.1. Filling the vacuum chamber with argon until the |
| | the simultaneous heating are completed, | pressure of 7 kPa is reached. After the chamber is |
| | the vacuum chamber is filled with | filled with argon, the temperature T₁ of the resistance |
| | argon, and then the temperature T₁ of | heater is increased from 500° C. to 750° C. for 2 hours. |
| | the resistance heater is increased. | 7.2. Fixing this temperature T₁ of 750° C. for the |
| | 7.2. Fixing this increased temperature | next 12 hours: during this time, the raw material is |
| | T₁ for melting the raw material: the raw | melted at this temperature. |
| | material melting process takes place. | 7.3. Increasing, at the rate of 5-30° C./hour, the |
| | The raw material in the container is | temperature T₁ of the resistance heater from 750° C. |
| | melted to form two phases: the melted | before the temperature T₂ of the side wall and/or the |
| | mass of the raw material and the skull | temperature T₃ of the bottom of the container falls |
| | layer that is a partially unmelted layer | within the interval 502° C.-529° C., i.e., the value |
| | of the raw material that is placed | that is 0.76-0.8 of the crystal melting temperature |
| | between the melted mass of the raw | value T₄ of 661° C., while avoiding exceeding the |
| | material and the aluminum foil layer. | value of 529° C. that is 0.8 of the crystal melting |
| | 7.3. In order to achieve the optimal | temperature value T₄ of 661° C., as well as avoiding |
| | thickness of the skull layer of 5-10 mm, | reduction to less than 502° C. that is 0.76 of the |
| | the raw material is further melted, while | crystal melting temperature value T₄. This increase |
| | controlling the temperature T₂ of the | of the temperatures T₁, T₂, T₃ is performed during: |
| | side wall and the temperature T₃ of the | 4 hours (Example 1), 8 hours (Example 2). |
| | bottom of the container until the | Example 1, Example 2: The values of the temperatures |
| | temperature T₂ of the side wall and/or | T₂ and T₃ have fallen within the interval 502-529° C., |
| | the temperature T₃ of the bottom of the | but the temperature T₃ of the container bottom has |
| | container falls into the interval | fallen first within this interval, so the fixing, i.e., |
| | 502° C.-529° C. being the temperature | termination of the increase of the temperature T₁ of |
| | value that corresponds to the | the resistance heater has been performed based on the |
| | temperature control criterion C_{tc}: | temperature T₃ of 507° C. that has been fixed after |
| | 0.76-0.8 of the crystal melting | the threshold of the temperature entrance 502° C. |
| | temperature value T₄ of 661° C., while | (Example 1); |
| | avoiding exceeding the value of | T₃ of 510° C. that has been fixed after the threshold |
| | 529° C. that is 0.8 of the crystal melting | of the temperature entrance 502° C. (Example 2). |
| | temperature value T₄ of 661° C., as | Example 1: the final temperature T₁ of the |
| | well as avoiding reduction to less than | resistance heater is 790° C. |
| | 502° C. that is 0.76 of the crystal | Example 2: the final temperature T₁ of the |
| | melting temperature value T₄. | resistance heater is 795° C. |
| 8 | Maintaining the obtained melt of the | Starting from the moment of fixation of the |
| | raw material. | temperature T₁ of the resistance heater, i.e., 790° C. |
| | | (Example 1), 795° C. (Example 2), this temperature |
| | | is maintained for 1-2 hours. |
| 9 | Directional crystallization of the | Gradual reduction of the above-mentioned |
| | obtained melt of the raw material. The | temperature T₁ of 790° C. (Example 1), 795° C. |
| | crystallization process of the melt starts | (Example 2), at the rate of 3° C./hour down to 680°. |
| | from the bottom, i.e., from the | At the temperature reduced down to 680° C., the |
| | container bottom being cooled and then | melt is crystallized completely. |
| | to the top towards the upper exposed | |
| | part of the container towards the | |
| | resistance heater. The crystallization | |
| | process continues until the complete | |
| | crystallization of the melt. | |
| 10 | Preparing the container with the crystal | After completion of the crystallization of the melt, |
| | for reloading into the annealing furnace. | the temperature T₁ of the resistance heater is reduced |
| | | from 680° C. down to 550° C. in 20-30 minutes, and |
| | | at this temperature of the resistance heater, the |
| | | temperature of the container that is measured by the |
| | | control thermocouples is within the interval of |
| | | 350° C.-400° C. |
| 11 | Reloading the hot container with the | The annealing furnace is pre-heated to the |
| | obtained crystal that is coated with the | temperature T₅ which is 0.832 of the crystal melting |
| | skull layer in the aluminum foil into the | temperature T₅, namely, to the temperature of 550° C. |
| | separate pre-heated annealing furnace. | |
| 12 | Annealing the crystal. | Annealing implies maintaining the crystal at the |
| | | above-mentioned temperature of 550° C. for 4 hours |
| | | (Example 1) and for 5 hours (Example 2). |
| 13 | Cooling the crystal. | The temperature T₅ is gradually reduced from |
| | | 550° C. down to room temperature, i.e., to the |
| | | temperature of 16-25°. |
| 14 | After the crystal is cooled, the | Specific parameters and characteristics are absent |
| | container with the crystal is transported | |
| | from the annealing furnace. The cooled | |
| | crystal that is coated with the skull | |
| | layer and the aluminum foil is removed | |
| | from the container. | |
| 15 | The double-layered protective shell is | Specific parameters and characteristics are absent |
| | removed from the cooled crystal: firstly, | |
| | the aluminum foil layer is removed | |
| | from the skull layer, and then, the skull | |
| | layer is removed from the crystal. | |

### EXAMPLE 1

The claimed method is performed as follows.

1. The internal working surface of the side walls and the bottom of the aluminum container, where the crystal will be grown, is coated with the metal aluminum foil having a thickness of 0.1 mm before loading the raw material. Dimensions of the container may be, for example: 500 mm×500 mm×170 mm. The container may have any arbitrary geometric shape: the container may have rectangular, cylindrical or any other shape.

The aluminum soft (annealed) or hard (non-annealed) foil having an aluminum content of at least 98.5% is used; the hard (non-annealed) foil is annealed after being exposed to the temperature of not more than 500° C. and becomes soft.

2. Then, the dry powdered raw material in a form of the mixture of sodium iodide NaI and thallium iodide TlI is loaded into the container in the general amount of 100 kg: 99 kg of NaI (99 wt. %) and 1 kg of the TlI activator (1 wt. %).

3. The container with the loaded raw material is mounted in the vacuum water-cooling chamber.

4. The thermocouples for measuring the temperature are secured to the bottom of the container and one of its side walls. At least two thermocouples are required: one thermocouple is to be located at the container bottom, while another thermocouple is to be located on one of its side walls. The thermocouples are connected to a temperature measurement unit.

5. The resistance heater having dimensions of 400×400 mm is positioned at a distance of 10 mm above the exposed upper part of the container with the raw material for melting this raw material and for subsequent temperature exposures onto the processing medium. The geometric shape of the heating working surface of the resistance heater corresponds to the shape of the exposed upper part of the container.

The resistance heater, particularly its heating working surface, is positioned horizontally and in parallel to the upper surface of the mass of the raw material loaded into the container, i.e., approximately in parallel to the surface of the future melt of this raw material. The area of the heating working surface of the resistance heater is less than the area of the exposed upper part of the container and, thus, the area of the heating working surface of the resistance heater is less than the area of the upper surface of the mass of the raw material loaded into the container (than the surface of the future melt of the raw material). Owing to this and to the heater parameters (its power), it becomes possible, during the subsequent melting of the raw material, to form and to maintain the partially unmelted layer of the raw material, i.e., the skull layer, along the internal surfaces of the walls and the bottom of the container, the skull layer prevents a contact between the melt of the raw material and the aluminum foil that coats the internal surfaces of the side walls and the bottom of the container.

6. Then, the vacuum cooling chamber is evacuated to forevacuum (i.e., to pre-vacuum) for 48 hours, while simultaneously heating the container and the raw material loaded therein. The heating of the container with the raw material is started simultaneously with the start of the evacuation. During 1 (one) hour from the start of evacuation and heating, the temperature T₁ of the resistance heater is increased up to the temperature of 300° C. and this temperature is fixed (maintained) for the next 23 hours of evacuation with the simultaneous heating at this temperature. Afterwards, i.e., 24 hours after the start of evacuation and the start of the simultaneous heating of the container and the raw material, the temperature T₁ of the resistance heater is increased up to the temperature of 500° C. for 1 (one) hour, and this temperature is fixed (maintained) during the entire remaining evacuation period, i.e., for the next 23 hours.

7. Producing the melt of the raw material.

7.1. After the above-mentioned 48 hours have passed, the evacuation is stopped, and in order to reduce the rate of evaporation of the raw material being melted, the vacuum chamber is filled with argon until the pressure of 7 kPa is reached, and after the inflow of argon during 2 hours, the temperature T₁ of the resistance heater is increased from 500° C. up to the temperature of 750° C.

7.2. Fixing, i.e., maintaining this temperature T₁ of 750° C. during the next 12 hours: during this time, the raw material is melted at this temperature. The raw material is melted and the processing media are formed, the processing media have various aggregate states, namely, the main melted mass of the raw material for growing the crystal and the skull layer, i.e., the partially unmelted layer of this raw material that is placed between the melted mass of the raw material and the aluminum foil layer that coats the internal working surface of the container. This skull layer is formed to avoid any contact between the melt of the main mass of the raw material and the aluminum foil layer. The skull layer and the aluminum foil layer together form the double-layered protective shell. However, the thickness of the skull layer that formed during the above-mentioned 12 hours at the temperature T₁ of the resistance heater being 750° C. is 30-50 mm that is not the optimal thickness therefore, since it is too high.

7.3. In order to ensure the optimal thickness of the skull layer of 5-10 mm, any further melting of the raw material is performed in the following way: the processing media (the melt of the raw material, the skull layer) are heated by a gradual increase of the temperature T₁ of the resistance heater, while controlling the temperature T₂ of the side wall and the temperature T₃ of the bottom of the container. The temperature T₁ of the heater is increased until one of the temperatures T₂ or T₃ reaches the specific value, and then, the temperature T₁ of the resistance heater is fixed, i.e., any further increase thereof is stopped. That is, while controlling the temperature T₂ of the side wall and the temperature T₃ of the bottom of the container, the temperature T₁ of the resistance heater is gradually (at the rate of 5-30° C./hour) is increased from the value of 750° C. until the temperature T₂ of the side wall and/or the temperature T₃ of the bottom of the container reaches, i.e., falls within the interval (range) of 502-529° C., i.e., the value that is 0.76-0.8 of the crystal melting temperature T₄ and is 661° C. (T₂ and/or T₃-(0.76×661° C.=0.8×661° C.), while avoiding falling beyond this range, i.e., lower than the limit of 0.76 of T₄, namely, not lower than 0.76×661° C., and higher than the limit of 0.8 of T₄, namely, not higher than 0.8×661° C.: i.e., the temperature T₁ of the resistance heater is correspondingly fixed and its increase is stopped after one of the temperatures T₂ or T₃ or both temperatures T₂ and T₃ simultaneously reached the value that falls within the interval (the range) of values that corresponds to the temperature control criterion C_{tc} of 0.76-0.8 of the value of the melting temperature T₄ of the crystal being grown. In this Example 1, the values of the temperatures T₂ and T₃ fell within the interval of 502-529° C., but not simultaneously: firstly, the temperature T₃ of the bottom of the container fell within this interval, thus, the temperature T₁ of the resistance heater was adjusted based on the temperature value of the bottom of the container being T₃=507° C. fixed after the threshold of the temperature entrance of 502° C.: the temperature T₁ of the resistance heater was fixed and its further increase was stopped.

This adjusted increase of the temperature T₁ based on controlling the values of the temperatures T₂, T₃ during further melting of the raw material was performed for 4 hours. In the provided example, the temperature T₁ of the resistance heater reaches the value of 790° C. And the value of the temperature of the side wall of the container is T₂=503° C.

8. The fixed temperature T₁ of the resistance heater of 790° C. at which the controlled temperatures are within the range of 502-529° C. are maintained for 2 hours: at this temperature and time mode, the melt of the raw material that is obtained by melting this raw material at the previous step is maintained.

The temperature T₂ of one of the side walls of the container was controlled in the upper external middle zone, while the temperature T₃ of the bottom of the container was controlled in the central external zone. Potentially, these areas are the hottest areas.

9. After the melt of the raw material and the formed skull layer of the optimal thickness are obtained, the directional crystallization of the melt is performed by gradual reduction of the above-mentioned temperature of the resistance heater being 790° C. at the rate of 3° C./hour down to 680° C. At the temperature reduced down to 680° C., the melt is crystallized. The crystallization process of the melt starts from the bottom, i.e., the crystallization process continues from the container bottom being cooled and then to the top (towards the upper exposed part of the container towards the resistance heater) until the melt is completely crystallized.

10. Preparing the container with the crystal for reloading into the annealing furnace.

After completion of the crystallization of the melt of the raw material, the temperature T₁ of the resistance heater is reduced from 680° C. down to 550° C. in 20-30 minutes, and at this temperature of the resistance heater, the temperature of the container that is measured by the control thermocouples is within the interval of 350° C.-400° C.

The skull layer that is formed during melting the raw material maintains its thickness and aggregate state during the entire crystallization process and further reduction of the temperature after its completion.

11. The hot container with the produced crystal that is coated with the double-layered shell, i.e., the skull layer in the aluminum foil, is reloaded to the separate annealing furnace having the internal working volume that is preliminarily heated to the temperature T₅ being 0.832 of the crystal melting temperature T₄. T₅=0.832×661° C., namely, to the temperature of 550° C.

12. In the annealing furnace, the crystal is annealed, i.e., it is maintained at the above-mentioned temperature of 550° C. for 4 hours.

13. Then, the temperature T₅ of 550° C. in the annealing furnace is gradually reduced down to the room temperature, i.e., 16-25° C.

14. After the gradual cooling of the crystal in the annealing furnace is completed, the container with the cooled crystal is transported from this furnace.

The cooled crystal that is coated with the skull layer and the aluminum foil layer is removed from the container.

15. Then, the double-layered protective shell is removed from the crystal: firstly, the aluminum foil layer is removed from the skull layer, since the foil is easily separated from the skull layer after cooling, and then the skull layer is removed from the crystal.

Implementation of the technological steps of the claimed process results in production of the scintillation alkali-halide high-quality crystal based on sodium iodide that is dopped with thallium, has a weight of 81 kg and dimensions of 470 mm×470 mm×100 mm. The crystal has a polycrystalline structure having a single-crystal blocks diameter of 5-50 mm. The thickness of the skull layer along the side walls and the bottom of the container is 7-10 mm.

This crystal is produced from the melt of the raw material without any contact between the melt and the container material that ensured reduction of the level of the internal stresses and production of the crystal without formation of any internal stresses during implementation of the technological process. The produced crystal does not comprise any internal stresses and does not crack during further processing.

### EXAMPLE 2

It is carried out in the same way as Example 1, but the raw material is used in the following quantitative ratio: 99.5 kg of NaI (99.5 wt. %) and 0.5 kg of TlI (0.5 wt. %), and after the internal surface of the container is coated with the aluminum foil having the thickness of 0.15 mm, the container is loaded with sodium iodide NaI in the amount of 99.5 kg, while thallium iodide (TlI) in the amount of 0.5 kg (0.5 wt. %) is loaded into the melted raw material before start of maintaining this melt of the raw material for 1 hour that is performed before the start of the crystallization process. TlI is loaded via a separate tube that is placed above the container center and passes through the resistance heater. The number of the thermocouples mounted on the container depends on the container structure and is as follows: two thermocouples at the bottom of the container and one thermocouple on either of the side walls. In this example, the controlled values of the temperatures T₂ and T₃ fell within the interval of 502-529° C. non-simultaneously: firstly, the temperature T₃ of the bottom of the container fell within this interval, thus, the temperature T₁ of the resistance heater was adjusted based on the temperature value of the bottom of the container being T₃=510° C. fixed after the threshold of the temperature entrance of 502° C.: the temperature T₁ was fixed and its further increase was stopped at the value of 795° C.

The crystal annealing time in the furnace is 5 hours.

The produced crystal has a polycrystalline structure having a single-crystal blocks diameter of 5-50 mm. The thickness of the skull layer along the side walls and the bottom of the container is 6-9 mm.

### EXAMPLE 3

It is carried out in the same way as Example 1, but the crystals are grown based on cesium iodide that is dopped with thallium and by corresponding technological elements depending on the dimensions of the crystal being grown.

Growing the CsI(Tl) crystal.

Dimensions of the container: 500 mm×500 mm×170 mm.

Loading the powdered raw material of thallium-dopped cesium iodide CsI(Tl).

The overall weight of the raw material is 120 kg: 118.8 kg of CsI (99 wt. %) and 1.2 kg of TlI (1 wt. %).

The thickness of the aluminum foil layer is 0.09 mm.

T₄ is the melting temperature of the crystal being grown, and it is 621° C.

T₂, T₃ are the temperatures of the side wall and the bottom of the container respectively: in the range of 472° C.-497° C., i.e., (0.76×T₄-0.8×T₄). In Example 3, the values of the temperatures T₂ and T₃ fell within the interval 472° C.-497° C. simultaneously, thus, the adjustment of the temperature T₁ of the resistance heater was performed based on the values of the temperature T₂ and T₃ from the moment when they fell within the interval 472° C.-497° C.: and at this moment, the temperature T₁ was fixed, i.e., its further increase above the value of 765° C. was stopped.

T₅ is the annealing temperature in the internal working volume of the annealing furnace being 497° C., i.e., (0.8×T₄), the annealing time is 2 hours.

The crystallization is performed until the temperature of 640° C. is reached. The rate of the reduction of the temperature of the resistance heater down to 640° C. is 3° C./hour.

Before reloading the container with the crystal to the separate annealing furnace, the temperature of the resistance heater is reduced down to the temperature of 500° C.

The weight of the produced crystal is 100 kg and the dimensions are 470×470×100 mm.

The produced crystal has a polycrystalline structure having a single-crystal blocks diameter of 5-50 mm. The thickness of the skull layer along the side walls and the bottom of the container is 6-8 mm.

### EXAMPLE 4

It is carried out in the same way as Example 1, but the crystals are grown based on cesium iodide that is dopped with sodium and by corresponding technological elements depending on the dimensions of the crystal being produced.

Growing the CsI(Na) crystal.

Dimensions of the container: 500 mm×500 mm×170 mm.

Loading the powdered raw material of cesium iodide CsI dopped with sodium iodide NaI.

The overall weight of the raw material is 120 kg: 119.7 kg of CsI (99.75 wt. %) and 0.3 kg of NaI (0.25 wt. %).

The thickness of the aluminum foil layer is 0.15 mm.

T₄ is the crystal melting temperature of 621° C.

T₂, T₃ are the temperatures of the side wall and the bottom of the container respectively, and they must be within the range of 472° C.-497° C., i.e., (0.76×T₄-0.8×T₄). In Example 4, the values of the temperatures T₂ and T₃ fell within the interval of 472° C.-497° C., but not simultaneously: firstly, the temperature T₂ of the side wall of the container fell within this interval, thus, the temperature T₁ of the resistance heater was adjusted based on the temperature value of the side wall of the container being T₂=478° C. fixed after the threshold of the temperature entrance of 472° C.: the temperature T₁ was fixed and its further increase was stopped at the value of 775° C.

T₅ is the annealing temperature in the separate annealing furnace being 497° C., i.e., (0.8×T₄), the annealing time is 1 hour.

The crystallization is performed until the temperature of 640° C. is reached. The rate of the reduction of the temperature of the resistance heater down to 640° C. is 1° C./hour.

Before reloading to the thermal insulation chamber, the temperature of the resistance heater is reduced down to the temperature of 500° C.

The weight of the crystal is 100 kg and the dimensions are 470 mm×470 mm×100 mm.

The produced crystal has a polycrystalline structure having a single-crystal blocks diameter of 5-50 mm. The thickness of the skull layer along the side walls and the bottom of the container is 5-8 mm.

### EXAMPLE 5

It is carried out in the same way as Example 4, but the crystal is grown based on CsI without additives and by corresponding technological elements depending on the dimensions of the crystal being produced.

Growing the CsI crystal.

Dimensions of the container: 500 mm×500 mm×170 mm.

Loading the powdered raw material of cesium iodide CsI.

The overall weight of the raw material is 120 kg: 120 kg of CsI (100 wt. %).

The thickness of the aluminum foil layer is 0.14 mm.

T₄ is the crystal melting temperature of 621° C.

T₂, T₃ are the temperatures of the walls or the bottom of the container, and it must be within the range of 472° C.-497° C., i.e., (0.76×T₄-0.8×T₄).

In Example 5, the values of the temperatures T₂ and T₃ fell within the interval of 472° C.-497° C., but not simultaneously: firstly, the temperature T₃ of the bottom of the container fell within this interval, thus, the temperature T₁ of the resistance heater was adjusted based on the temperature value of the bottom of the container being T₃=475° C. fixed after the threshold of the temperature entrance of 472° C.: the temperature T₁ was fixed and its further increase was stopped at the value of 770° C.

T₅ is the annealing temperature in the annealing furnace being 497° C., i.e., (0.8×T₄), the annealing time is 3 hours.

The crystallization is performed until the temperature of 640° C. is reached. The rate of the reduction of the temperature of the resistance heater down to 640° C. is 1° C./hour.

Before reloading to the separate annealing furnace, the temperature of the resistance heater is reduced down to the temperature of 500° C.

The weight of the crystal is 100 kg, and the dimensions are 470 mm×470 mm×100 mm.

The produced crystal has a polycrystalline structure having a single-crystal blocks diameter of 5-50 mm. The thickness of the skull layer along the side walls and the bottom of the container is 8-10 mm.

The above-mentioned Examples 1, 2, 3, 4, 5 of the specific practical implementation of the claimed process are the most preferred exemplary embodiments of the invention within the industrial technology.

The claimed process, according to the provided Examples 1, 2, 3, 4, 5, has been reproduced in the experimental and manufacturing conditions for the required number of times in order to obtain average testing results of this technology that have confirmed the achievement of the technical effects upon implementation of the present process.

Comparative characteristics of weight of the crystal, weight, and thickness of the skull layer which were obtained during experimental tests of the claimed process, namely, during implementation of the technologies according to the closest analog and according to the claimed process, are provided in Table 2.

TABLE 2

| | Electrical energy | Electrical energy |
|---|---|---|
| | consumption, kW | consumption, kW |
| Step of the | The closest | The claimed |
| technological process | analog | process |
| 1 | 2 | 3 |
| Evacuation | 72 | 64.8 |
| Melting the raw material | 115 | 103.5 |
| Growing the crystal | 192 | 172.8 |
| Annealing the crystal | 14 | 8 |
| Cooling the crystal | 180 | 60 |
| IN TOTAL at the | 573 | 409.1 |
| above-mentioned | | |
| steps, kW | | |
| IN TOTAL at the | 100% | 71% |
| above-mentioned | | |
| steps, % | | |

The number of technological cycles (%) implemented to ensure the thickness of the formed skull layer of 5-10 mm:

Along the internal side surface of the container:
65% for the closest analog;
100% for the claimed process.

Along the internal surface of the bottom of the container:
20% for the closest analog;
100% for the claimed process.

The number of technological cycles (%) implemented to ensure the thickness of the formed skull layer of greater than 10 mm:

Along the internal side surface of the container:
35% for the closest analog;
0% for the claimed process.

Along the internal surface of the bottom of the container:
80% for the closest analog;
0% for the claimed process.

The number of technological cycles (%) implemented to ensure complete melting of the skull layer along the side wall or the bottom of the container that resulted in a discharge of the melt from the container (emergency situation):
10% for the closest analog;
0% for the claimed process.

The claimed process allows to increase the efficiency of the process for growing the crystal, namely, to increase the crystal weight by up to 10% as compared to the closest analog. This became possible due to control of the thickness of the skull layer along the bottom of the container, thereby allowing to assuredly reduce its thickness down to the optimal thickness of 5-10 mm.

Comparative values of electrical energy consumption which were obtained during experimental tests of the claimed process, i.e., during implementation of the technologies according to the closest analog and according to the claimed process, are provided in Table 3.

TABLE 3

| | Electrical energy | Electrical energy |
|---|---|---|
| | consumption, kW | consumption, kW |
| Step of the | The closest | The claimed |
| technological process | analog | process |
| 1 | 2 | 3 |
| Evacuation | 72 | 64.8 |
| Melting the raw material | 115 | 103.5 |
| Growing the crystal | 192 | 172.8 |
| Annealing the crystal | 14 | 8 |
| Cooling the crystal | 180 | 60 |
| IN TOTAL at the | 573 | 409.1 |
| above-mentioned | | |
| steps, kW | | |
| IN TOTAL at the | 100% | 71% |
| above-mentioned | | |
| steps, % | | |

Owing to use of the aluminum foil as well as conduction of annealing and cooling of the crystal in the separate annealing furnace, electrical energy consumption for production of the crystal according to the claimed process are reduced by 29% as compared to the closest analog.

Industrial applicability and achievement of the technical effects upon application of the claimed process have been confirmed many times during conduction of experimental and manufacturing tests.

The conducted tests of the claimed technology have confirmed the achievement of the technical effects upon implementation of the present process.

The implementation of the novel technological cycles, the novel set of the technological steps of the claimed process resulted in:
production of crack-free crystals, i.e., polycrystals, having the assured high quality without any internal stresses due to elimination of accumulation of these stresses and cracking of the polycrystal along boundaries of the single-crystal blocks;
production of the crystals, i.e., polycrystals, having the increased dimensions and the increased weight, and, thus, increase of the process efficiency by up to 10% due to reduction of the raw material mass that is consumed for the formation of the skull layer;
reduction of energy consumption for conduction of the process by down to 29%.

The claimed process meets all the requirements of equipment operation and usage, as well as the common safety rules.

Use of the claimed process will also allow to expand the range of modern technologies for producing crystals of various sizes, including large-sized crystals, namely, large-area polycrystals.

1. A process for producing crystals, the process comprises steps of loading a raw material into a container, placing the container loaded with the raw material into a cooling vacuum chamber that is evacuated to forevacuum, heating and melting the raw material in a skull to form an optimal thickness of a skull layer by means of a resistance heater positioned above the container and in parallel to a melt surface of the raw material, the resistance heater has a working heating surface having an area that is less than an area of an exposed upper part of the container and it has parameters that allow to produce the skull layer along inner surfaces of walls and bottom of the container having a thickness of 5-10 mm, further directional crystallizing the melt of the raw material by reducing a temperature of the resistance heater according to a given program, annealing the produced crystal, cooling the annealed crystal, separating the skull layer, wherein the process comprises, before the step of loading the container with the raw material, coating an inner surface of the container for growing the crystal with a protective metal foil layer having a thickness of 0.04-0.15 mm, and the steps of producing the melt of the raw material, directional crystallizing, annealing and cooling the annealed crystal are performed in a double-layered protective shell that is formed along the inner surfaces of the walls and the bottom of the container by the protective metal foil layer and the skull layer of the raw material, and the step of melting the raw material comprises adjusting a temperature T₁ of the resistance heater based on controlling measurement values of a temperature T₂ of a side wall of the container and a temperature T₃ of the bottom of the container, while correspondingly fixing the temperature T₁ of the resistance heater immediately after either one of the temperatures T₂ or T₃ or both temperatures T₂ and T₃ simultaneously reached a value that falls within an interval of values that corresponds to a temperature control criterion C_{tc} that is 0.76-0.8 of a crystal melting temperature value T₄ of the crystal being grown, namely, C_{tc}=(0.76×T₄):(0.8×T₄), and after the step of directional crystallizing is completed, the step of annealing the crystal is performed in a separate annealing furnace at a temperature T₅ having a value of 0.8-0.9 of the crystal melting temperature value T₄ of the crystal being grown.

2. The process according to claim 1, wherein an aluminum foil layer having an aluminum content of at least 98.5% is used as a metal component of the double-layered protective shell.

3. The process according to claim 1, wherein the step of melting the raw material comprises controlling the temperature measurement value T₂ of one of the side walls of the container that is performed in an upper external middle zone of the side wall of the container, while controlling the temperature measurement value T₃ of the bottom of the container is performed in a central external zone of the bottom of the container.

4. The process according to claim 1, wherein the further melting the raw material for formation and maintaining the optimal thickness of the skull layer within 5-10 mm by adjusting the temperature T₁ of the resistance heater based on controlling the temperature measurement values T₂ and T₃ according to the interval of values of the temperature control criterion C_{tc}=(0.76×T₄):(0.8×T₄) takes place for 4-8 hours after pre-heating and pre-melting the raw material, and then the produced melt of the raw material having the formed skull layer is maintained for 1-2 hours.

5. The process according to claim 1, wherein an inner working volume of the separate annealing furnace is heated to the temperature T₅ before the container with the crystal is loaded therein, and the crystal is annealed at this temperature for 1-5 hours.

6. The process according to claim 1, wherein after the steps of annealing and cooling the crystal, the double-layered protective shell is separated from the annealed and cooled crystal successively, namely, firstly, the aluminum foil layer is separated from the skull layer, and then, the skull layer is separated from the crystal.
